(19) United States
(12) Patent Application Publication
(10) Pub. No.: US 2024/0349553 A1
(43) Pub. Date: Oct. 17, 2024

(54) DISPLAY PANEL AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Cong LIU, Beijing (CN); Yanwei LU, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/294,015

(22) PCT Filed: May 5, 2023
(86) PCT No.: PCT/CN2023/092207

§ 371 Date: Jan. 31, 2024

(30) Foreign Application Priority Data
May 31, 2022 (CN) 202210612200.7

(51) Int. Cl. H10K 59/131; G09G 3/3266

(52) U.S. Cl. CPC H10K 59/131; G09G 3/3266; G09G 2310/0286

(57) ABSTRACT

A display panel has a display region and a peripheral region surrounding the display region, and includes: a substrate, a plurality of data lines located in the display region, and a first compensation structure located in the peripheral region. Lengths of at least two of the data lines are not equal. The first compensation structure includes first electrodes, a second electrode and a third electrode; each of the first electrodes is electrically connected to a data line, and the second electrode is configured to transmit a common voltage signal; and orthographic projections of the first electrodes, the second electrode and the third electrode on the substrate have overlapping regions.

### CROSS-REFERENCE TO RELATED APPLICATIONS

This application is a national phase entry under 35 USC 371 of International Patent Application No. PCT/CN2023/092207, filed on May 5, 2023, which claims priority to Chinese Patent Application No. 202210612200.7, filed on May 31, 2022, which are incorporated herein by reference in their entirety.

### TECHNICAL FIELD

The present disclosure relates to the field of display technologies, and in particular, to a display panel and a display apparatus.

### BACKGROUND

With the development of display technologies, display apparatuses (such as mobile phones, notebook computers, or tablet computers) are increasingly used in people's lives. Organic light-emitting diode (OLED) display apparatuses have received widespread attention due to their advantages of active light emission, wide viewing angle, high contrast, fast response speed, low power consumption, ultra-thin, etc.

### SUMMARY

In an aspect, embodiments of the present disclosure provide a display panel, and the display panel has a display region and a peripheral region surrounding the display region. The display panel further includes a substrate, a plurality of data lines and a first compensation structure. The plurality of data lines are located in the display region, and lengths of at least two of the plurality of data lines are not equal. The first compensation structure is located in the peripheral region, and the first compensation structure includes a plurality of first electrodes, at least one second electrode and at least one third electrode. Each first electrode is electrically connected to a data line; the at least one second electrode is configured to transmit a common voltage signal; orthographic projections of the plurality of first electrodes, the at least one second electrode, and the at least one third electrode on the substrate have overlapping regions.

In some embodiments, the display panel further includes an active layer, a first gate conductive layer, a second gate conductive layer, a source-drain conductive layer, and an anode layer that are stacked in a direction perpendicular to the substrate and away from the substrate. The first electrodes are located in the first gate conductive layer, the second electrode is located in the second gate conductive layer, and the plurality of data lines are located in the source-drain conductive layer.

In some embodiments, the third electrode is located in the active layer, and a material of the third electrode includes a conductive semiconductor material. In some embodiments, the display panel further includes a plurality of pixel circuits, an initialization signal bus, a gate driving circuit, a first connection line and a second connection line. The plurality of pixel circuits are located in the display region. The plurality of pixel circuits are arranged in a plurality of rows and a plurality of columns, and each column of pixel circuits is electrically connected to at least one data line. The initialization signal bus is located in the peripheral region and at least partially surrounds the display region. The first connection line is located in the source-drain conductive layer. An end of the first connection line is electrically connected to the gate driving circuit, and another end of the first connection line is electrically connected to a row of pixel circuits. The second connection line is located in the source-drain conductive layer. An end of the second connection line is electrically connected to the initialization signal bus, and another end of the second connection line is electrically connected to a row of pixel circuits. The first compensation structure is located between the plurality of pixel circuits and the initialization signal bus, and the first connection line and the second connection line extend above the first compensation structure.

In some embodiments, the third electrode is located in the source-drain conductive layer.

In some embodiments, the display panel further includes a plurality of pixel circuits, an initialization signal bus, a gate driving circuit, a first connection line and a second connection line. The plurality of pixel circuits are located in the display region. The plurality of pixel circuits are arranged in a plurality of rows and a plurality of columns. Each column of pixel circuits is electrically connected to at least one data line. The initialization signal bus is located in the peripheral region and at least partially surrounds the display region. The gate driving circuit is located on a side of the initialization signal bus away from the display region. The first connection line is located in the anode layer. An end of the first connection line is electrically connected to the gate driving circuit, and another end of the first connection line is electrically connected to a row of pixel circuits. The second connection line is located in the anode layer. An end of the second connection line is electrically connected to the initialization signal bus, and another end of the second connection line is electrically connected to a row of pixel circuits. The first compensation structure is located between the plurality of pixel circuits and the initialization signal bus, and the first connection line and the second connection line extend above the first compensation structure.

In some embodiments, the common voltage signal is a voltage drain drain (VDD) signal. The display panel further includes a VDD bus and a plurality of VDD signal lines. The VDD bus is located between the first compensation structure and the initialization signal bus, and is located in the source-drain conductive layer. The plurality of VDD signal lines are located in the display region, and are located in the source-drain conductive layer. Each column of pixel circuits is electrically connected to a VDD signal line. The plurality of VDD signal lines are electrically connected to the VDD bus. The at least one second electrode is electrically connected to the plurality of VDD signal lines.

In some embodiments, the display panel further includes a third connection line; an end of the third connection line is electrically connected to the second connection line, and another end of the third connection line is electrically connected to the initialization signal bus; and the third connection line is located in the second gate conductive layer and extends below the VDD bus.

In some embodiments, the display panel further includes a test unit, a fourth connection line and a fifth connection line. An end of the fourth connection line is electrically connected to the test unit, and another end of the fourth connection line is electrically connected to a first electrode. The fourth connection line is located in the first gate conductive layer and extends below the VDD bus and the initialization signal bus. An end of the fifth connection line is electrically connected to the gate driving circuit, and another end of the fifth connection line is electrically connected to the first connection line. The fifth connection line is located in the first gate conductive layer and extends below the VDD bus and the initialization signal bus.

In some embodiments, the second electrode is a floating electrode.

In some embodiments, the first compensation structure includes a plurality of first electrodes and a plurality of second electrodes, each second electrode corresponds to a first electrode, and orthographic projections of the first electrode and the second electrode that correspond to each other on the substrate overlap; or, the first compensation structure includes a plurality of first electrodes and one second electrode, and orthographic projections of the plurality of first electrodes on the substrate overlap with an orthographic projection of the second electrode on the substrate.

In some embodiments, the first compensation structure includes a plurality of first electrodes and a plurality of third electrodes, each third electrode corresponds to a first electrode, and orthographic projections of the first electrode and the third electrode that correspond to each other on the substrate overlap; or, the first compensation structure includes a plurality of first electrodes and one third electrode, and orthographic projections of the plurality of first electrodes on the substrate overlap with an orthographic projection of the third electrode on the substrate.

In some embodiments, the display region is approximately circular; in a first direction and from two sides of the display region to a center line of the display region along a second direction, length of the plurality of data lines increase in a stepwise manner; the second direction is parallel to an extension direction of the data lines; and the first direction is perpendicular to the second direction. Borders of the display region include two opposite first straight line borders, two opposite second straight line borders, and four polyline borders. The first straight line borders extend along the second direction; the second straight line borders extend along the first direction; and each polyline border is located between adjacent first straight line border and second straight line border. Among the four polyline borders, two polyline borders close to a bonding region are first polyline borders, and two polyline borders far away from the bonding region are second polyline borders; sides of the two first polyline borders away from a center of the display region are each provided with one first compensation structure, and/or sides of the two second polyline borders away from the center of the display region are each provided with one first compensation structure.

In some embodiments, sides of the four polyline borders away from the center of the display region are each provided with one first compensation structure.

In some embodiments, the display panel further includes a gate driving circuit and a second compensation structure. The gate driving circuit is located on a side of the first compensation structure away from the display region. The gate driving circuit includes a plurality of shift register sub-circuits, and at least a group of two adjacent shift register sub-circuits has a first gap therebetween. The second compensation structure includes at least one fourth electrode, at least one fifth electrode and at least one sixth electrode; the at least one fourth electrode is located in the first gap, each fourth electrode is electrically connected to a first electrode, and orthographic projections of the at least one fourth electrode, the at least one fifth electrode and the at least one sixth electrode on the substrate have an overlapping region.

In some embodiments, the second compensation structure includes a plurality of fourth electrodes, and a number of the fourth electrodes is equal to a number of the first electrodes.

In some embodiments, a border of the display region is approximately circular. The second compensation structure includes a plurality of fourth electrodes, and a number of the fourth electrodes is less than a number of the first electrodes. Lines connecting centers of the plurality of fourth electrodes to a center of the display region have included angles in a range from 30° to 50° with a first direction. The first direction is perpendicular to an extension direction of the data lines.

In some embodiments, the second compensation structure includes a plurality of fifth electrodes and a plurality of sixth electrodes; each fifth electrode corresponds to a sixth electrode, and the fifth electrode and the sixth electrode that correspond to each other are located in the same first gap; two adjacent fifth electrodes and two adjacent sixth electrodes have at least one shift register sub-circuit therebetween; and orthographic projections of the fifth electrode, the sixth electrode and at least one fourth electrode located in the same first gap on the substrate overlap.

In some embodiments, the at least one fourth electrode and the first electrodes are arranged in the same layer; the at least one fifth electrode and the second electrode are arranged in the same layer; and the at least one sixth electrode and the third electrode are arranged in the same layer.

In another aspect, the embodiments of the present disclosure further provide a display panel, and the display panel has a display region and a peripheral region surrounding the display region. The display panel includes a substrate, a gate driving circuit, a plurality of data lines and a third compensation structure. The gate driving circuit includes a plurality of shift register sub-circuits, at least a group of two adjacent shift register sub-circuits has a first gap therebetween, and the gate driving circuit and the display region have a second gap therebetween. The plurality of data lines are located in the display region, and lengths of at least two of the plurality of data lines are not equal. The third compensation structure is located in the peripheral region and includes a plurality of first electrodes and at least one second electrode that are located in the second gap, and at least one fourth electrode and at least one fifth electrode that are located in the first gap. Each first electrode is electrically connected to a data line, and an orthographic projection of the at least one second electrode on the substrate overlaps with orthographic projections of the plurality of first electrodes on the substrate. Each fourth electrode is electrically connected to a first electrode, the at least one fifth electrode is electrically connected to the at least one second electrode, and an orthographic projection of the at least one fifth electrode on the substrate overlaps with an orthographic projection of the at least one fourth electrode on the substrate.

In some embodiments, the display panel further includes an active layer, a first gate conductive layer, a second gate conductive layer, a source-drain conductive layer, and an anode layer that are stacked in a direction perpendicular to the substrate and away from the substrate. The first electrodes and the fourth electrode are located in the first gate conductive layer; and the second electrode and the fifth electrode are located in the second gate conductive layer.

In some embodiments, the display panel further includes a fifth connection line and a sixth connection line. The fifth connection line is located in the first gate conductive layer, an end of the fifth connection line is electrically connected to the first electrode, and another end of the fifth connection line is electrically connected to a fourth electrode. The sixth connection line is located in the first gate conductive layer, an end of the sixth connection line is electrically connected to a second electrode, and another end of the sixth connection line is electrically connected to a fifth electrode.

In some embodiments, the third compensation structure includes a plurality of fourth electrodes, and a number of the fourth electrodes is equal to a number of the first electrodes.

In some embodiments, a shape of the display region is approximately circular; the third compensation structure includes a plurality of fourth electrodes; a number of the fourth electrodes is less than a number of the first electrodes; lines connecting the plurality of fourth electrodes to a center of the display region have included angles in a range from 30° to 50° with a first direction. The first direction is perpendicular to an extension direction of the data lines.

In some embodiments, the third compensation structure includes a plurality of fifth electrodes; two adjacent fifth electrodes have at least one shift register sub-circuit therebetween; and orthographic projections of a fifth electrode and at least one fourth electrode located in the same first gap on the substrate overlap.

In yet another aspect, the embodiments of the present disclosure provide a display apparatus, and the display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, and are not limitations on actual sizes of products involved in the embodiments of the present disclosure.

FIG. 1 is a structural diagram of a display apparatus in some embodiments of the present disclosure;

FIG. 2 is a structural diagram of a display panel in some embodiments of the present disclosure;

FIG. 3A is a sectional view taken along the section line A-A in FIG. 2;

FIG. 3B is a partial enlarged view of the region C in FIG. 2;

FIG. 4A is a sectional view taken along the section line D-D in FIG. 3B;

FIG. 4B is another sectional view taken along the section line D-D in FIG. 3B;

FIG. 5 is a structural diagram of a first gate conductive layer in some embodiments of the present disclosure;

FIG. 6A a structural diagram of a second gate conductive layer in some embodiments of the present disclosure;

FIG. 6B a structural diagram of another second gate conductive layer in some embodiments of the present disclosure;

FIG. 7A is a structural diagram of an active layer in some embodiments of the present disclosure;

FIG. 7B is a structural diagram of another active layer in some embodiments of the present disclosure;

FIG. 8 is a structural diagram of a source-drain conductive layer in some embodiments of the present disclosure;

FIG. 9 is a partial enlarged view of the region E in FIG. 3B;

FIG. 10 is another partial enlarged view of the region C in FIG. 2;

FIG. 11A is a sectional view taken along the section line F-F in FIG. 10;

FIG. 11B is another sectional view taken along the section line F-F in FIG. 10;

FIG. 12A is a structural diagram of another source-drain conductive layer in some embodiments of the present disclosure;

FIG. 12B is a structural diagram of yet another source-drain conductive layer in some embodiments of the present disclosure;

FIG. 13 is a structural diagram of an anode layer in some embodiments of the present disclosure;

FIG. 14A is a structural diagram of another display panel in some embodiments of the present disclosure;

FIG. 14B is a structural diagram of yet another display panel in some embodiments of the present disclosure;

FIG. 14C is a structural diagram of yet another display panel in some embodiments of the present disclosure;

FIG. 15 is yet another partial enlarged view of the region C in FIG. 2;

FIG. 16 is a sectional view taken along the section line G-G in FIG. 15;

FIG. 17 is a structural diagram of yet another display panel in some embodiments of the present disclosure;

FIG. 18 is a structural diagram of another display apparatus in some embodiments of the present disclosure;

FIG. 19 is a structural diagram of yet another display panel in some embodiments of the present disclosure;

FIG. 20 is a partial enlarged view of the region H in FIG. 19;

FIG. 21 is a structural diagram of a first gate conductive layer of a display panel in some embodiments of the present disclosure;

FIG. 22 is a structural diagram of a second gate conductive layer of a display panel in some embodiments of the present disclosure;

FIG. 23 is a structural diagram of a source-drain conductive layer of a display panel in some embodiments of the present disclosure; and

FIG. 24 is a structural diagram of yet another display panel in some embodiments of the present disclosure.

### DETAILED DESCRIPTION

The technical solutions in embodiments of the present disclosure will be described clearly and completely with reference to the accompanying drawings in embodiments of the present disclosure. However, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

Unless the context requires otherwise, throughout the specification and the claims, the term “comprise/include”, “comprises/includes” or “comprising/including” is construed as an open and inclusive meaning, i.e., “including, but not limited to. In the description of the specification, the term such as “an embodiment”, “some embodiments”, “exemplary” or “for example” is intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

In the description of the present disclosure, it will be understood that, orientations or positional relationships indicated by the terms such as “center”, “above”, “below”, “left”, “right”, “vertical”, “horizontal” are based on orientations or positional relationships shown in the drawings, which is merely for convenience in description of the present disclosure and simplifying the description, but not to indicate or imply that the indicated apparatus or element must have a particular orientation, or be constructed and operated in a particular orientation. Therefore, these terms should not be construed as limitations on the present application.

The terms “first” and “second” are used for descriptive purposes only, and are not to be construed as indicating or implying a relative importance or implicitly indicating a number of indicated technical features. Thus, features defined with “first” and “second” may explicitly or implicitly include one or more of the features. In the description of the present disclosure, the term “multiple”, “a plurality of” or “the plurality of” means two or more unless otherwise specified.

In the description of the present application, it will be noted that the term “communicated” or “connected” is to be understood broadly. For example, it may be a fixed connection, a detachable connection, or an integral connection; it may be a mechanical connection or an electrical connection; and it may be a direct connection, or may be an indirect connection through an intermediate medium, and may be internal communication between two elements. Specific meanings of the above terms in the present disclosure may be understood by those skilled in the art according to specific situations.

The phrase “configured to” used herein means an open and inclusive expression, which does not exclude devices that are configured to perform additional tasks or steps.

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

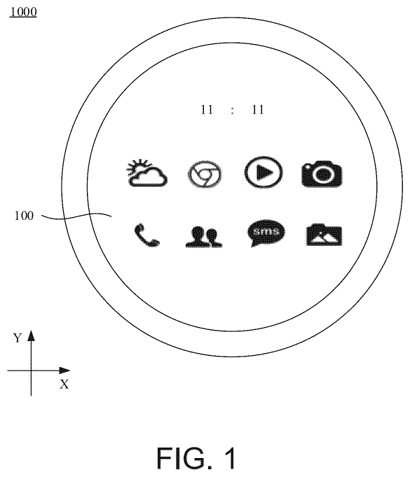

Some embodiments of the present disclosure provide a display apparatus 1000. As shown in FIG. 1, the display apparatus 1000 may be an apparatus or device for visually displaying electronic information. For example, the display apparatus 1000 may include one of a smart phone, a tablet computer, a notebook computer, a television, and a smart watch. For example, the display apparatus 1000 includes a smart watch.

For example, the display apparatus 1000 may be an organic light-emitting diode (OLED) display apparatus, or a quantum dot light-emitting diode (QLED) display apparatus, or an active matrix organic light-emitting diode (AMOLED) display apparatus.

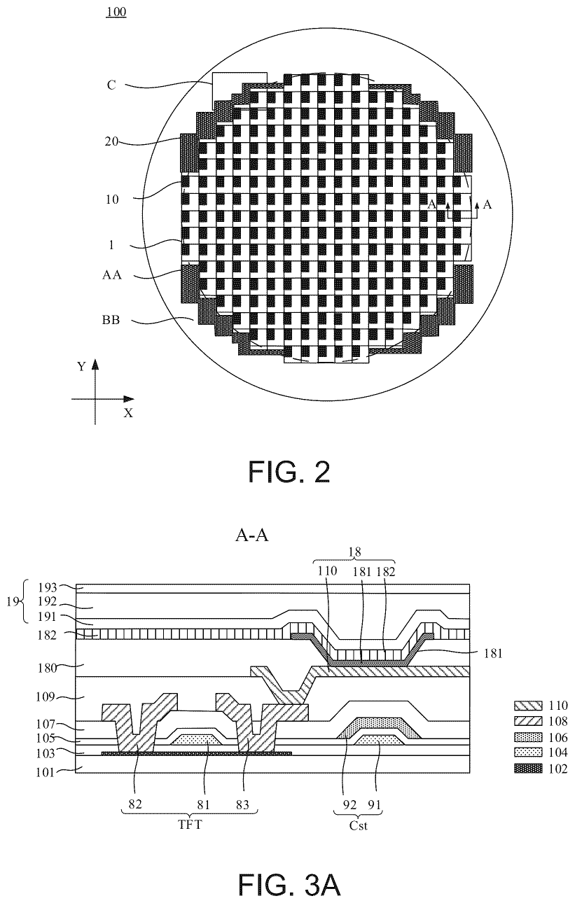

In some embodiments, the display apparatus 1000 includes a display panel 100. As shown in FIG. 2, the display panel 100 has a display region AA and a peripheral region BB surrounding the display region AA. The display region AA is provided therein with a plurality of pixel circuits 10, and the plurality of pixel circuits 10 are arranged into a plurality of rows of pixel circuits 10 and a plurality of columns of pixel circuits 10. Each row of pixel circuits 10 includes pixel circuits 10 arranged along a first direction X, and each column includes pixel circuits 10 arranged along a second direction Y. The plurality of pixel circuits 10 are disposed on a substrate (which is not shown in the figure).

In a special-shaped display panel, there is a situation where at least two columns of pixel circuits 10 include different numbers of pixel circuits 10. In this way, lengths of data lines 1 connected to the at least two columns of pixel circuits 10 are different. That is, the data lines 1 connected to the at least two columns of pixel circuits 10 have different resistive-capacitive (RC) loadings, which may lead to the risk of poor display of the special-shaped display panel 100.

The special-shaped display panel is in a shape of one of the followings: a fan, arc, circle, cylinder and triangle. For example, the special-shaped display panel may be in a shape of a circle.

In some embodiments, when the shape of the display panel 100 is circular, as shown in FIG. 2, the shape of the display region AA is approximately circular.

The pixel circuit 10 also includes a storage capacitor and a driving thin film transistor (TFT). In the case where the shape of the display panel 100 is circular, as shown in FIG. 2, the middle column of pixel circuits 10 in the display region AA includes the largest number of pixel circuits 10, and the data line 1 connected thereto has the largest RC loading; and when the pixel circuit 10 performs the data writing, the storage capacitor in the pixel circuit 10 is not fully charged, and the gate voltage of the driving TFT is a first voltage at this time. One or more columns of pixel circuits 10 on two (outermost) sides include the smallest number of pixel circuits 10, and the data lines 1 connected thereto have the smallest RC loading; when the pixel circuit 10 performs the data writing, the storage capacitor in the pixel circuit 10 is fully charged, and the gate voltage of the driving TFT is a second voltage, the first voltage being less than the second voltage. According to the working principle of the pixel circuit 10, when realizing a pure color and same grayscale image, the gate voltages of the driving TFTs of the middle column of pixel circuits 10 are less than the gate voltages of the driving TFTs of the outermost column of pixel circuits 10, resulting in difference in brightness of a display region corresponding to the middle column of pixel circuits 10 and a display region corresponding to the outermost column of pixel circuits 10.

In the related art, in order to reduce the risk of poor display of the display panel, compensation capacitor(s) are provided in the peripheral region of the display panel so that the RC loading of each column of data lines in the display region is approximately equal. The compensation capacitor generally includes two electrode plates opposite to each other. The electrode plates generally have large areas and require a certain layout space in the peripheral region, which is not conducive to reducing the width of the peripheral region of the display panel.

In order to solve the above problems, as shown in FIG. 2, the display panel 100 provided in the embodiments of the present disclosure further includes a first compensation structure 20, and the first compensation structure 20 is located in the peripheral region BB.

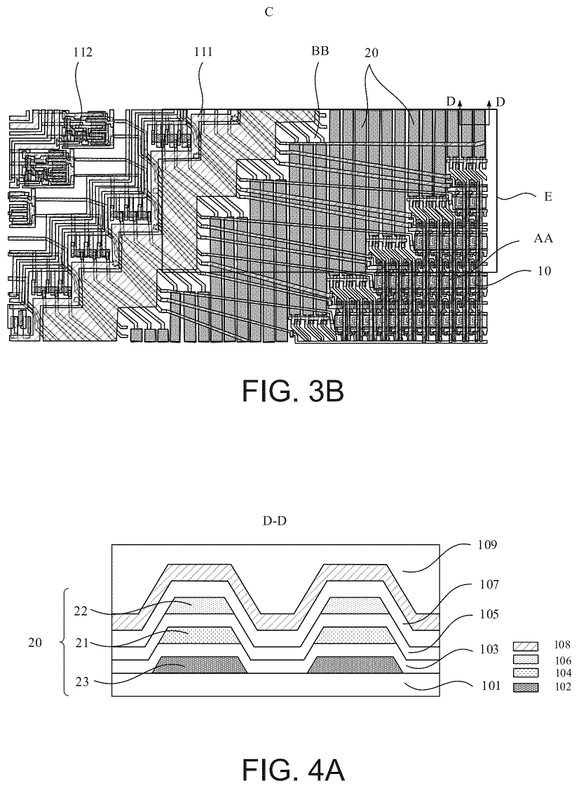

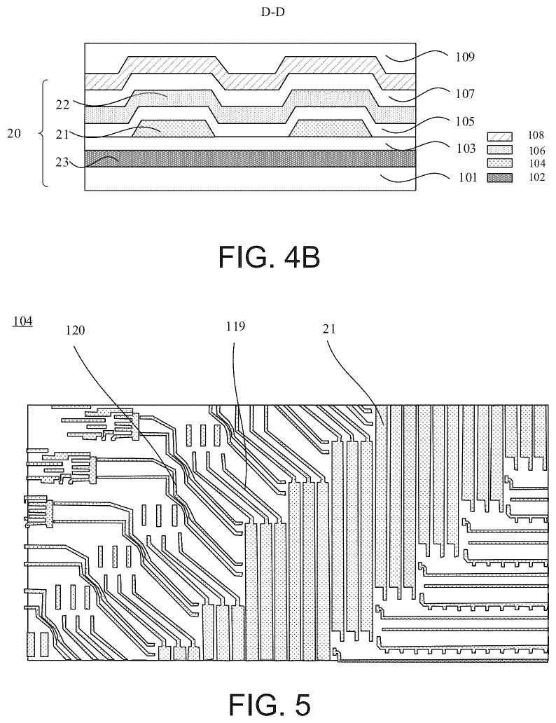

As shown in FIGS. 3B, 4A and 4B, the first compensation structure 20 includes first electrodes 21, a second electrode 22 and a third electrode 23. Each first electrode 21 is electrically connected to a data line 1. In this way, the first compensation structure 20 can perform RC loading compensation on the data lines 1, so that the data lines 1 of different lengths have approximately equal RC loading, and the risk of poor display of the display panel 100 is reduced. The second electrode 22 is configured to transmit a common voltage signal. For example, the common voltage signal may be a voltage drain drain (VDD) voltage signal. The third electrode 23 is a floating electrode. The floating electrode means that only an electrode pattern is provided and the electrode pattern is not electrically connected to any signal line or circuit. During the operation of the display panel 100, no electrical signal is loaded to the electrode pattern.

Orthographic projections of the first electrode 21, the second electrode 22 and the third electrode 23 on the substrate 101 have an overlapping region. That is, the orthographic projections of the first electrode 21, the second electrode 22 and the third electrode 23 on the substrate 101 overlap in the same region. An orthographic projection of the first electrode 21 on the substrate 101 and an orthographic projection of the second electrode 22 on the substrate 101 overlap, so that the first electrode 21 and the second electrode 22 can form a first compensation capacitor. Similarly, the first electrode 21 and the third electrode 23 can also form a second compensation capacitor. In this way, the first electrode 21, the second electrode 22 and the third electrode 23 can form two compensation capacitors connected in parallel, which may increase the RC loading per unit area compensated by the first compensation structure 20. Compared with the related art, under the same compensated RC loading, the first compensation structure 20 can be made smaller, thus reducing the space occupied by the first compensation structure 20 in the peripheral region BB, and in turn reducing the width of the peripheral region BB of the display panel 100.

In some embodiments, as shown in FIG. 3A, the display panel 100 further includes an active layer 102, a first gate dielectric layer 103, a first gate conductive layer 104, a second gate dielectric layer 105, a second gate conductive layer 106, an interlayer dielectric layer 107, a source-drain conductive layer 108, a planarization layer 109 and an anode layer 110 that are stacked in a direction perpendicular to the substrate 101 and away from the substrate 101 (a direction from bottom to top in FIG. 3A).

The active layer 102 is disposed on the substrate. The active layer 102 is made of a semiconductor material which may include at least one of polysilicon (P—Si), cadmium oxide (CdO), aluminum trioxide (Al₂O₃), indium gallium zinc oxide (IGZO), indium tin oxide (InSnO), indium zinc oxide (InZnO), tin dioxide (SnO₂), indium trioxide (In₂O₃), zinc oxide (ZnO) or carbon nanotube (CNT).

The first gate dielectric layer 103 is disposed on a side of the active layer 102 away from the substrate 101. The first gate dielectric layer 103 is made of an insulating material which may include at least one of silicon nitride (SiNₓ), aluminum oxide (Al₂O₃), or silicon oxide (SnO₂).

The first gate conductive layer 104 is disposed on a side of the first gate dielectric layer 103 away from the substrate 101. The material of the first gate conductive layer 104 is a conductor, which may include at least one of aluminum (Al), silver (Ag), or copper (Cu).

The second gate dielectric layer 105 is disposed on a side of the first gate conductive layer 104 away from the substrate 101. The second gate dielectric layer 105 may be made of the same material as the first gate dielectric layer 103.

The second gate conductive layer 106 is disposed on a side of the second gate dielectric layer 105 away from the substrate 101. The second gate conductive layer 106 may be made of the same material as the first gate conductive layer 104.

The interlayer dielectric layer 107 is disposed on a side of the second gate conductive layer 106 away from the substrate 101. The interlayer dielectric layer 107 may be made of the same material as the first gate dielectric layer 103.

The source-drain conductive layer 108 is disposed on a side of the interlayer dielectric layer 107 away from the substrate 101. The source-drain conductive layer 108 may be made of the same material as the first gate conductive layer 104.

The planarization layer 109 is disposed on the side of the interlayer dielectric layer 107 away from the substrate 101. The planarization layer 109 may be made of the same material as the first gate dielectric layer 103.

The anode layer 110 is disposed on a side of the planarization layer 109 away from the substrate 101. The material of the anode layer 110 is a conductor, which may include at least one of indium tin oxide (ITO), indium zinc oxide (IZO), gold (Au), silver (Ag), magnesium-silver alloy, or aluminum-lithium alloy.

The display panel 100 further includes a pixel definition layer 180, a light-emitting functional layer 181 and a cathode layer 182. Overlapping portions of orthographic projections, on the substrate 101, of the anode layer 110 (for providing holes), a light-emitting functional layer 181 and the cathode layer 182 can constitute a light-emitting device 18. The anode layer 110 and the cathode layer 182 respectively inject holes and electrons into the light-emitting functional layer 181, and light is emitted when the excitons generated by the combination of holes and electrons transitions from an excited state to a ground state.

The display panel 100 further includes an encapsulation layer 19, and the encapsulation layer 19 is disposed on a side of the cathode layer 182 away from the substrate 101. The encapsulation layer 19 may be an encapsulation film. The number of layers of encapsulation films included in the encapsulation layer 19 is not limited. In some embodiments, the encapsulation layer 19 may include one layer of encapsulation film, or two or more layers of encapsulation films that are stacked. The encapsulation layer 19 includes a first inorganic encapsulation layer 191, an organic encapsulation layer 192 and a second inorganic encapsulation layer 193 that are arranged in sequence in the direction perpendicular to the substrate 101 and away from the substrate 101. The material of the first inorganic encapsulation layer 191 and the material of the second inorganic encapsulation layer 193 each include any one or more of silicon nitride (SiNₓ), silicon oxynitride (SiON) or silicon oxide (SiOₓ). The material of the organic encapsulation layer 192 includes a polymer resin, such as polyimide.

The first gate conductive layer 104 includes gates 81 of a plurality of TFTs and first electrode plates 91 of a plurality of storage capacitors Cst. The second gate conductive layer 106 includes second electrode plates 92 of the plurality of storage capacitors Cst. The source-drain conductive layer 108 includes sources 82 and drains 83 of the plurality of TFTs.

In some embodiments, as shown in FIG. 5, the first electrodes 21 are located in the first gate conductive layer 104. The first electrodes 21 and the first gate conductive layer 104 may be formed through one patterning process, thereby reducing the number of patterning times, saving manufacturing costs and improving manufacturing efficiency.

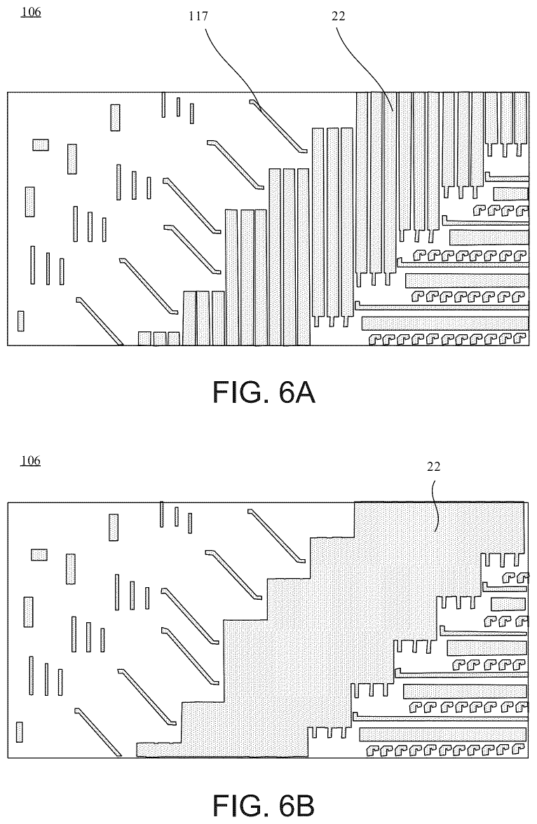

In some embodiments, as shown in FIGS. 6A and 6B, the second electrode 22 is located in the second gate conductive layer 106. The second electrode 22 and the second gate conductive layer 106 may be formed through one patterning process, thereby reducing the number of patterning times, saving manufacturing costs and improving manufacturing efficiency.

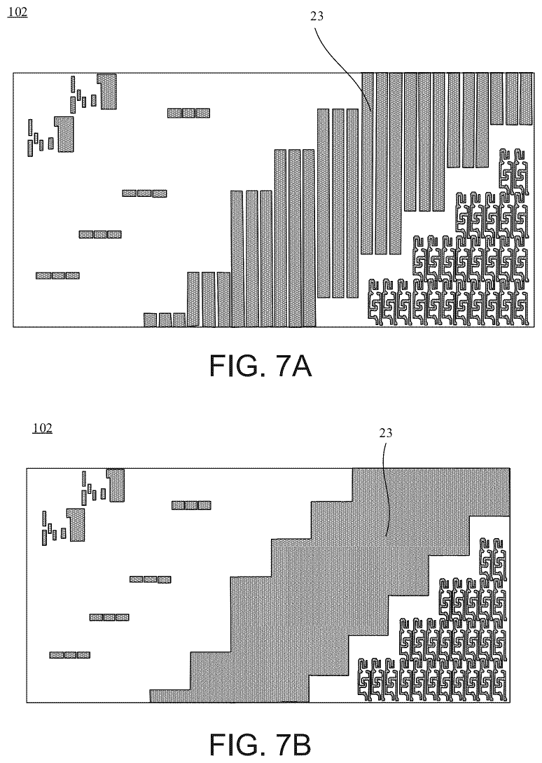

In some embodiments, as shown in FIGS. 7A and 7B, the third electrode 23 is located in the active layer 102, and the material of the third electrode 23 includes a conductive semiconductor material. The third electrode 23 and the active layer 102 may use the same semiconductor material, and an undoped pattern is formed through one patterning process, which may reduce the number of patterning times, save manufacturing costs and improve manufacturing efficiency. Before the first gate conductive layer 104 is arranged, there is a need to use a mask to expose the third electrode 23, and then the third electrode 23 becomes a conductor through a doping process. After the first gate conductive layer 104 is formed, a portion of the active layer 102 except the third electrode 23 exposed by the first gate conductive layer 104 is doped to be conductive using the first gate conductive layer as a mask layer. That is, the active layer 102 and the third electrode 23 are doped to be conductive in different processes.

In the case where the third electrode 23 is located in the active layer 102, as shown in FIGS. 4A and 4B, the first electrode 21 and the second electrode 22 constitute a first compensation capacitor, and an insulating layer between the first electrode 21 and the second electrode 22 is made of the second gate dielectric layer 105. The first electrode 21 and the third electrode 23 constitute a second compensation capacitor, and an insulating layer between the first electrode 21 and the third electrode 23 is made of the first gate dielectric layer 103. The first compensation capacitor and the second compensation capacitor use the first electrode 21 as a common electrode. Two compensation capacitors share one electrode, so that the first compensation structure is simple, and the process steps can be reduced.

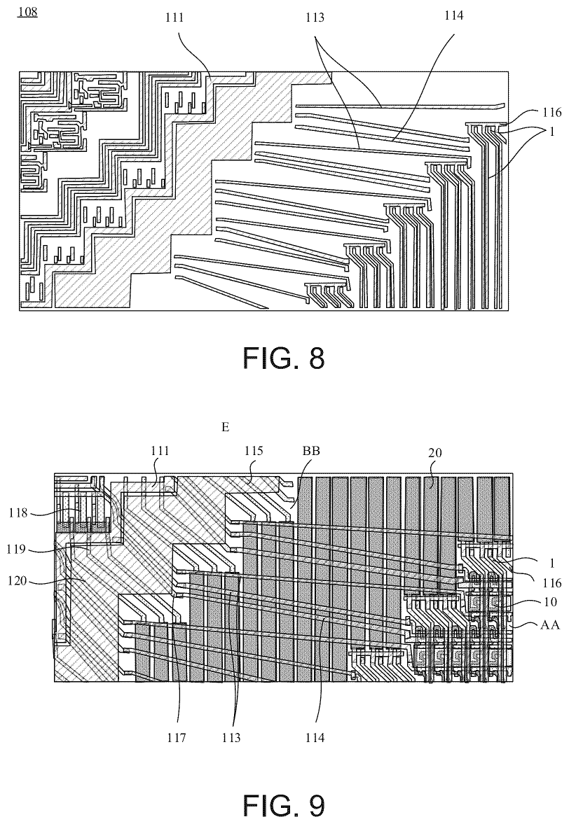

In some embodiments, as shown in FIG. 8, a plurality of data lines 1 are located in the source-drain conductive layer 108. The plurality of data lines 1 and the source-drain conductive layers 108 may be formed through one patterning process, thereby reducing the number of patterning times, saving the manufacturing costs and improving the manufacturing efficiency.

In some embodiments, as shown in FIGS. 3B and 9, the display panel 100 further includes an initialization signal bus 111, a gate driving circuit 112, first connection line(s) 113 and second connection line(s) 114.

The initialization signal bus 111 is located in the peripheral region BB and at least partially surrounds the display region AA. The initialization signal bus 111 is configured to initialize voltages of two ends of a storage capacitor and a voltage of an anode of a light-emitting element. The gate driving circuit 112 is located on a side of the initialization signal bus 111 away from the display region AA.

As shown in FIG. 8, the first connection line(s) 113 are located in the source-drain conductive layer 108. An end of the first connection line 113 is electrically connected to the gate driving circuit 112, and another end of the first connection line 113 is electrically connected to a row of pixel circuits 10. The second connection line(s) 114 are located in the source-drain conductive layer 108. An end of the second connection line 114 is electrically connected to the initialization signal bus 111, and another end of the second connection line 114 is electrically connected to a row of pixel circuits 10.

The first compensation structure 20 is located between the plurality of pixel circuits 10 and the initialization signal bus 111, and the first connection line(s) 113 and the second connection line(s) 114 extend above the first compensation structure 20.

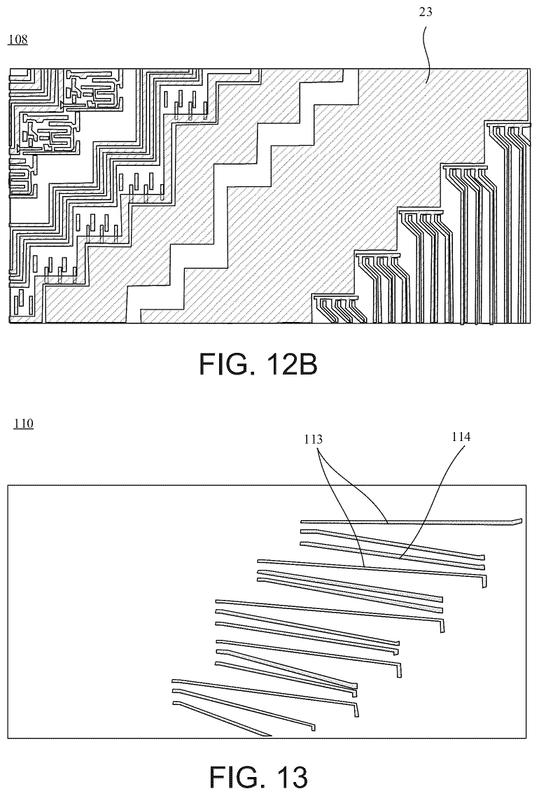

In some embodiments, as shown in FIGS. 12A and 12B, the third electrode 23 is located in the source-drain conductive layer 108. The third electrode 23 and the source-drain conductive layer 108 may be formed through one patterning process, which may reduce the number of patterning times, save the manufacturing costs and improve the manufacturing efficiency. During the process of forming the third electrode 23, since the material of the source-drain conductive layer 108 is a conductor, when the third electrode 23 is located in the source-drain conductive layer 108, there is no need to use a mask to expose the third electrode 23 and change the third electrode 23 to a conductor through a doping process. In this way, it may be possible to save the number of used masks, save the manufacturing costs, and improve the manufacturing efficiency.

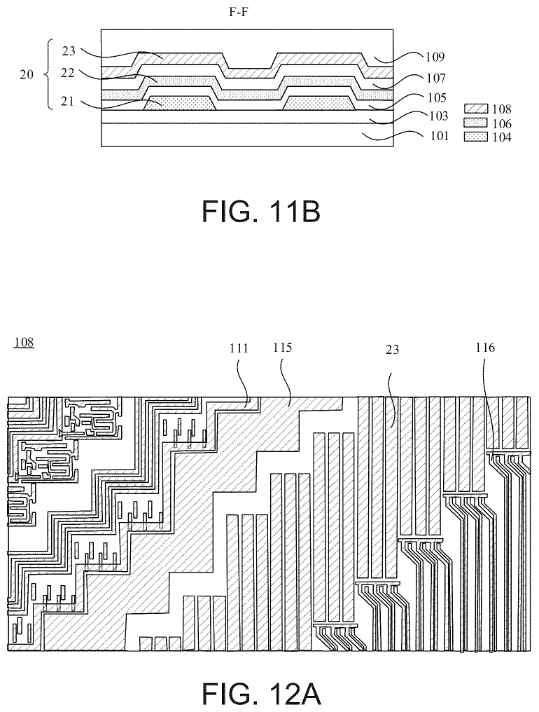

As shown in FIGS. 11A and 11B, in the case where the third electrode 23 is located in the source-drain conductive layer 108, the first electrode 21 and the second electrode 22 constitute a first compensation capacitor, and an insulating layer between the first electrode 21 and the second electrode 22 is made of the second gate dielectric layer 105. The first electrode 21 and the third electrode 23 constitute a second compensation capacitor, and an insulating layer between the first electrode 21 and the third electrode 23 is made of the interlayer dielectric layer 107 and the second gate dielectric layer 105. The first compensation capacitor and the second compensation capacitor use the first electrode 21 as a common electrode. Two compensation capacitors share one electrode, so that the first compensation structure 20 has a simple structure, and the process steps can be reduced.

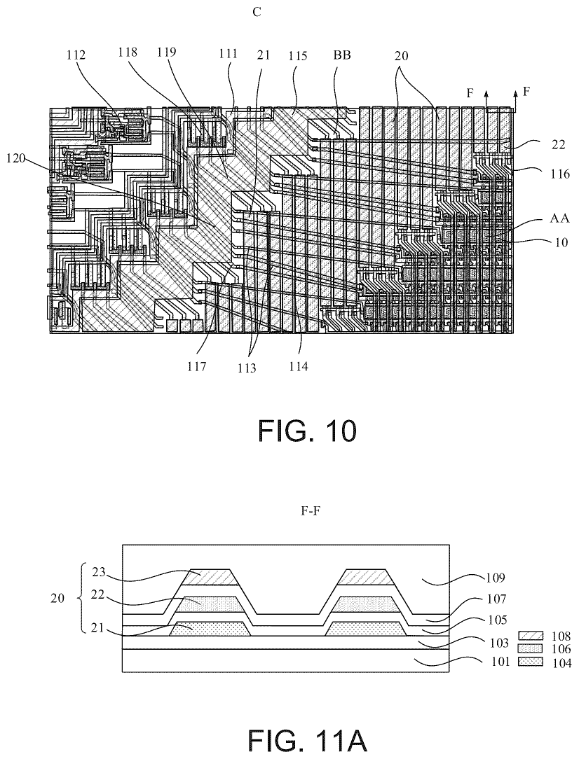

As shown in FIG. 10, the gate driving circuit 112 is located on the side of the initialization signal bus 111 away from the display region AA, and the first connection line(s) 113 are located in the anode layer 110 (as shown in FIG. 13). An end of the first connection line 113 is electrically connected to the gate driving circuit 112, and another end of the first connection line 113 is electrically connected to a row of pixel circuits 10. The second connection line(s) 114 are located in the anode layer. An end of the second connection line 114 is electrically connected to the initialization signal bus 111, and another end of the second connection line 114 is electrically connected to a row of pixel circuits 10.

The first compensation structure 20 is located between the plurality of pixel circuits 10 and the initialization signal bus 111, and the first connection line(s) 113 and the second connection line(s) 114 extend above the first compensation structure 20.

In some embodiments, as shown in FIGS. 9 and 10, the common voltage signal is the VDD signal, and the display panel 100 further includes a VDD bus 115 and a plurality of VDD signal lines.

The VDD bus 115 is located between the first compensation structure 20 and the initialization signal bus 111, and is located in the source-drain conductive layer 108 (as shown in FIGS. 8 and 12A).

The plurality of VDD signal lines 116 are located in the display region AA and in the source-drain conductive layer 108; each column of pixel circuits 10 is electrically connected to a VDD signal line 116; and the plurality of VDD signal lines 116 are electrically connected to the VDD bus 115. The second electrode 22 is electrically connected to the plurality of VDD signal lines 116.

In some embodiments, as shown in FIG. 9, the display panel 100 further includes third connection line(s) 117. An end of the third connection line 117 is electrically connected to a second connection line 114, and another end of the third connection line 117 is electrically connected to the initialization signal bus 111. The third connection line(s) 117 are located in the second gate conductive layer 106 and extend below the VDD bus 115.

In some embodiments, as shown in FIG. 10, the display panel 100 further includes a test unit 118, fourth connection line(s) 119 and fifth connection line(s) 120.

The test unit 118 is located between the gate driving circuit 112 and the initialization signal bus 111. An end of the fourth connection line 119 is electrically connected to the test unit 118, and another end of the fourth connection line 119 is electrically connected to a first electrode 21. The fourth connection line(s) 119 are located in the first gate conductive layer 104, and extend below the VDD bus 115 and the initialization signal bus 111. An end of the fifth connection line 120 is electrically connected to the gate driving circuit 112, and another end of the fifth connection line 120 is electrically connected to a first connection line 113. The fifth connection line(s) 120 are located in the first gate conductive layer 104, and extend below the VDD bus 115 and the initialization signal bus 111.

In some embodiments, the first compensation structure 20 includes a plurality of first electrodes 21 and a plurality of second electrodes 22; or, the first compensation structure 20 includes a plurality of first electrodes 21 and one second electrode 22.

As shown in FIGS. 4A and 11A, in the case where the first compensation structure 20 includes a plurality of second electrodes 22, each second electrode 22 corresponds to a first electrode 21. That is, the number of the second electrodes 22 is equal to the number of the first electrodes 21.

An orthographic projection of the first electrode 21 on the substrate 101 and an orthographic projection of the second electrode 22 on the substrate 101 have an overlapping region, which refers to that a boundary of an orthographic projection of each first electrode 21 on the substrate 101 completely or partially overlaps a boundary of an orthographic projection of a second electrode 22 corresponding to the first electrode 21 on the substrate 101. In the case where the boundary of the orthographic projection of each first electrode 21 on the substrate 101 completely overlaps the boundary of the orthographic projection of the second electrode 22 corresponding to the first electrode 21 on the substrate 101, the boundary of the orthographic projection of each first electrode 21 on the substrate 101 coincides with the boundary of the orthographic projection of the second electrode 22 corresponding to the first electrode 21 on the substrate 101. In the case where the boundary of the orthographic projection of each first electrode 21 on the substrate 101 partially overlaps the boundary of the orthographic projection of the second electrode 22 corresponding to the first electrode 21 on the substrate 101, the boundary of the orthographic projection of each first electrode 21 on the substrate 101 is located in the boundary of the orthographic projection of the second electrode 22 corresponding to the first electrode 21 on the substrate 101, and the boundary of the orthographic projection of each first electrode 21 on the substrate 101 and the boundary of the orthographic projection of the second electrode 22 corresponding to the first electrode 21 on the substrate 101 are spaced; or, the boundary of the orthographic projection of each first electrode 21 on the substrate 101 is partially located within the boundary of the orthographic projection of the second electrode 22 corresponding to the first electrode 21 on the substrate 101, and is partially located outside the boundary of the orthographic projection of the second electrode 22 corresponding to the first electrode 21 on the substrate 101.

For example, the boundary of the orthographic projection of the first electrode 21 on the substrate 101 coincides with the boundary of the orthographic projection of the second electrode 22 corresponding to the first electrode 21 on the substrate 101. In this way, the area occupied by the first compensation structure 20 on the substrate 101 may be reduced. Thus, the width of the peripheral region BB of the display panel 100 may be reduced. The plurality of second electrodes 22 are arranged in parallel, and the resistance of the second electrodes 22 that are connected in parallel is small, thus reducing the voltage drop of the VDD signal.

As shown in FIGS. 4B and 11B, in the case where the first compensation structure 20 includes one second electrode 22, the orthographic projections of the first electrode 21 and the second electrode 22 on the substrate 101 have an overlapping region, which refers to that: the boundary of the orthographic projection of each first electrode 21 on the substrate 101 is located within the boundary of the orthographic projection of the second electrode 22 on the substrate 101; or the boundary of the orthographic projection of each first electrode 21 on the substrate 101 is partially located within the boundary of the orthographic projection of the second electrode 22 on the substrate 101, and is partially located outside the boundary of the orthographic projection of the second electrode 22 on the substrate 101. For example, the boundary of the orthographic projection of each first electrode 21 on the substrate 101 is located within the boundary of the orthographic projection of the second electrode 22 on the substrate 101. In this way, the area occupied by the first compensation structure 20 on the substrate 101 may be reduced. Thus, the width of the peripheral region BB of the display panel 100 may be reduced.

In some embodiments, the first compensation structure 20 includes a plurality of first electrodes 21 and a plurality of third electrodes 23; or, the first compensation structure 20 includes a plurality of first electrodes 21 and one third electrode 23.

As shown in FIGS. 4A and 11A, in the case where the first compensation structure 20 includes a plurality of third electrodes 23, each third electrode 23 corresponds to a first electrode 21. That is, the number of the third electrodes 23 is the same as the number of the first electrodes 21.

An orthographic projection of the first electrode 21 on the substrate 101 and an orthographic projection of the third electrode 23 on the substrate 101 have an overlapping region, which refers to that a boundary of an orthographic projection of each first electrode 21 on the substrate 101 completely or partially overlaps a boundary of an orthographic projection of a third electrode 23 corresponding to the first electrode 21 on the substrate 101. In the case where the boundary of the orthographic projection of each first electrode 21 on the substrate 101 completely overlaps the boundary of the orthographic projection of the third electrode 23 corresponding to the first electrode 21 on the substrate 101, the boundary of the orthographic projection of each first electrode 21 on the substrate 101 coincides with the boundary of the orthographic projection of the third electrode 23 corresponding to the first electrode 21 on the substrate 101. In the case where the boundary of the orthographic projection of each first electrode 21 on the substrate 101 partially overlaps the boundary of the orthographic projection of the third electrode 23 corresponding to the first electrode 21 on the substrate 101, the boundary of the orthographic projection of each first electrode 21 on the substrate 101 is located in the boundary of the orthographic projection of the third electrode 23 corresponding to the first electrode 21 on the substrate 101, and the boundary of the orthographic projection of each first electrode 21 on the substrate 101 and the boundary of the orthographic projection of the third electrode 23 corresponding to the first electrode 21 on the substrate 101 are spaced; or, the boundary of the orthographic projection of each first electrode 21 on the substrate 101 is partially located within the boundary of the orthographic projection of the third electrode 23 corresponding to the first electrode 21 on the substrate 101, and is partially located outside the boundary of the orthographic projection of the third electrode 23 corresponding to the first electrode 21 on the substrate 101.

For example, the boundary of the orthographic projection of the first electrode 21 on the substrate 101 coincides with the boundary of the orthographic projection of the third electrode 23 corresponding to the first electrode 21 on the substrate 101. In this way, the area occupied by the first compensation structure on the substrate 101 may be reduced. Thus, the width of the peripheral region BB of the display panel 100 may be reduced.

As shown in FIGS. 4B and 11B, in the case where the first compensation structure 20 includes one third electrode 23, the orthographic projections of the first electrode 21 and the third electrode 23 on the substrate 101 have an overlapping region, which refers to that: the boundary of the orthographic projection of each first electrode 21 on the substrate 101 is located within the boundary of the orthographic projection of the third electrode 23 corresponding to the first electrode 21 on the substrate 101; or, the boundary of the orthographic projection of each first electrode 21 on the substrate 101 is partially located within the boundary of the orthographic projection of the third electrode 23 corresponding to the first electrode 21 on the substrate 101, and is partially located outside the boundary of the orthographic projection of the third electrode 23 corresponding to the first electrode 21 on the substrate 101. For example, the boundary of the orthographic projection of each first electrode 21 on the substrate 101 is located within the boundary of the orthographic projection of the third electrode 23 corresponding to the first electrode 21 on the substrate 101. In this way, the area occupied by the first compensation structure 20 on the substrate 101 may be reduced. Thus, the width of the peripheral region BB of the display panel 100 may be reduced. When a mask is used for evaporating the third electrode 23 onto the substrate 101, an opening corresponding to the third electrode 23 in the mask is large, and the mask is easy to process and has a simple structure.

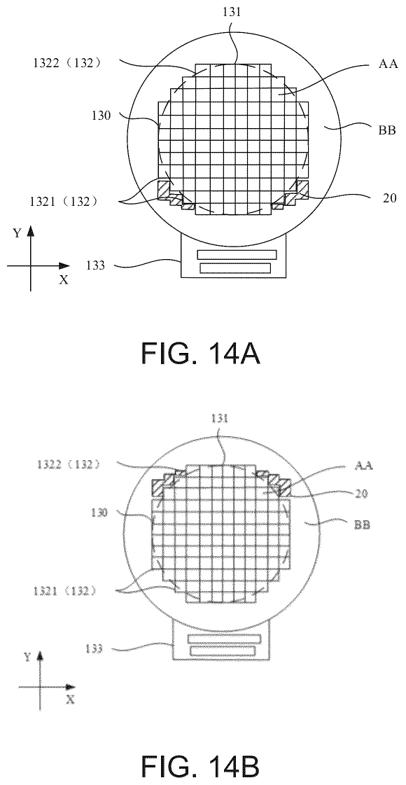

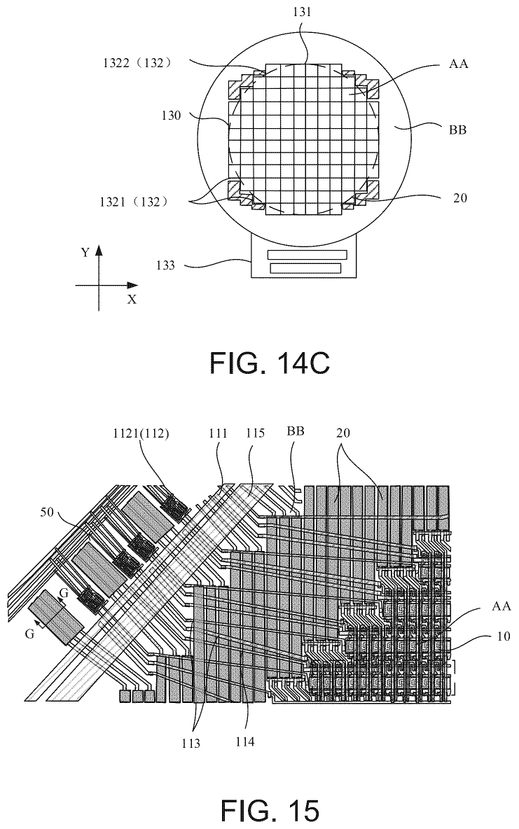

In some embodiments, as shown in FIG. 14A, the shape of the display region AA is approximately circular; in the first direction X, and from two sides of the display region AA to the center line of the display region AA along the second direction Y, the lengths of a plurality of data lines 1 increase in a stepwise manner. In other words, from the two sides of the display region AA to the middle of the display region AA, the lengths of a plurality of data lines 1 in the second direction Y increase in a stepwise manner. That is to say, from the two sides of the display region AA to the middle of the display region AA, the compensated RC loadings required by the data lines 1 are decreasing. Generally, the longest data line 1 in the display region AA is used as a compensation reference, and a data line 1 with a short length is compensated for the RC loading. The second direction Y is parallel to the extension direction of the data lines 1, and the first direction X is perpendicular to the second direction Y.

As shown in FIG. 14A, borders of the display region AA include: two opposite first straight line borders 130, two opposite second straight line borders 131, and four polyline borders 132. The first straight line borders 130 extend along the second direction Y, the second straight line borders 131 extend along the first direction X, and each polyline borders 132 is located between adjacent first straight line border 130 and second straight line border 131. The first straight line borders 130 and the second straight line borders 131 are connected in sequence through the four polyline borders 132.

Among the four polyline borders 132, two polyline borders 132 close to a bonding region 133 are first polyline borders 1321, and two polyline borders 132 far away from the bonding region 133 are second polyline borders 1322. Sides of the two first polyline borders 1321 away from the center of the display region AA are each provided with one first compensation structure 20. Alternatively, as shown in FIG. 14B, sides of the two second polyline borders 1322 away from the center of the display region AA are each provided with one first compensation structure 20. In this way, it may be possible to reduce the width of the peripheral region BB of the display panel 100.

In some embodiments, as shown in FIG. 14C, first compensation structures 20 are arranged on sides of the four polyline borders 132 away from the display region AA of the substrate 101, respectively. Since the first compensation structure 20 has a small size, the space occupied by the first compensation structure 20 in the peripheral region BB is small, which may reduce the width of the peripheral region BB of the display panel 100.

In some embodiments, as shown in FIG. 15, the gate driving circuit 112 is located on a side of the first compensation structure 20 away from the display region AA of the substrate 101; the gate driving circuit 112 includes a plurality of shift register sub-circuits 1121; and at least a group of two adjacent shift register sub-circuits 1121 has a first gap 50 therebetween.

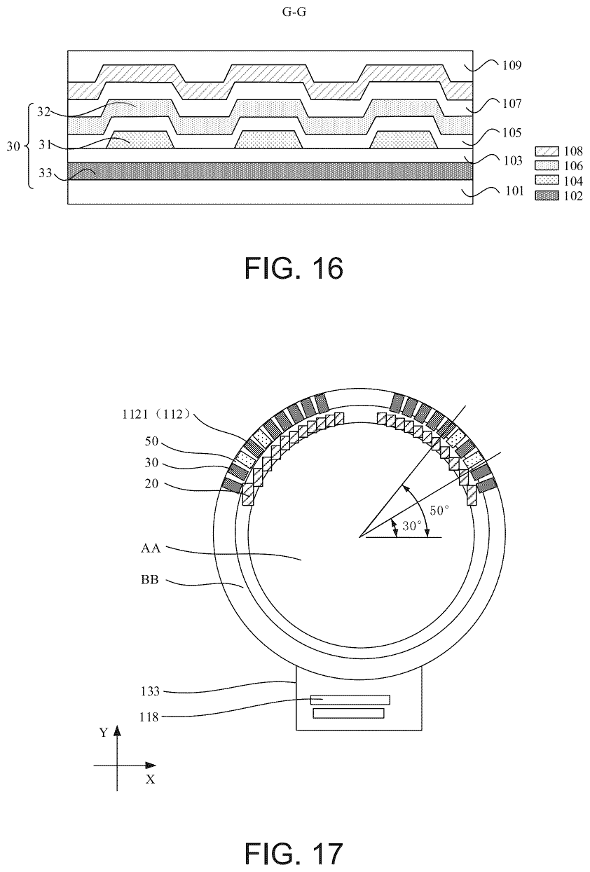

In some embodiments, the display panel 100 further includes a second compensation structure 30, and as shown in FIG. 16, the second compensation structure 30 includes at least one fourth electrode 31, at least one fifth electrode 32, and at least one sixth electrode 33. Orthographic projections of the at least one fourth electrode 31, the at least one fifth electrode 32, and the at least one sixth electrode 33 on the substrate 101 have an overlapping region. That is, the at least one fourth electrode 31 and the at least one fifth electrode 32 constitute a third compensation capacitor, and the at least one fourth electrode 31 and the at least one sixth electrode 33 constitute a fourth compensation capacitor. Each fourth electrode 31 is electrically connected to a first electrode 21. That is, the first compensation structure 20 and the second compensation structure 30 together perform the RC loading compensation on the data lines 1. The at least one fourth electrode 21 is located in the first gap 50. That is, the second compensation structure 30 is located in the first gap 50. The second compensation structure 30 may compensate part of RC loadings required by the data lines 1. In this way, the first compensation structure 20 located between the display region AA and the initialization signal bus 111 may be made smaller, and the space occupied by the first compensation structure 20 in the peripheral region BB is reduced, so that the width of the peripheral region BB of the display panel 100 can be reduced.

In some embodiments, the fifth electrode 32 may be electrically connected to the second electrode 22, or the fifth electrode 32 may be a floating electrode. The sixth electrode 33 may be electrically connected to the third electrode 23.

In some embodiments, the second compensation structure 30 includes a plurality of fourth electrodes 31, the number of the fourth electrodes 31 is equal to the number of the first electrodes 21, and one fourth electrode 31 is electrically connected to one first electrode 21. In this way, the volume of each first electrode 21 located between the display region AA and the initialization signal bus 111 can be made smaller. Therefore, the volume of the first compensation structure 20 is smaller, and the space occupied by the first compensation structure 20 in the peripheral region BB is smaller. As a result, the width of the peripheral region BB of the display panel 100 can be reduced.

In some embodiments, the shape of display region AA is approximately circular. The second compensation structure 30 includes a plurality of fourth electrodes 31, and the number of the fourth electrodes 31 is less than the number of the first electrodes 21. As shown in FIG. 17, in the case where the shape of the display region AA is circular, the compensated RC loadings required by the data lines 1 are decreasing from the two sides of the display region AA to the middle of the display region AA; the volumes of the first compensation structures 20 connected to the data lines 1 are decreasing from the two sides of the display region AA to the middle of the display region AA. The first compensation structures 20 connected to the data lines 1 on the two sides of the display region AA have the largest volumes, and the first compensation structures 20 connected to the data lines 1 in the middle of the display region AA have the smallest volumes. The fourth electrodes 21 are electrically connected to the first electrodes 21 that are electrically connected to the data lines 1 on the two sides of the display region AA. In this way, the volumes of the first electrodes 21 that are electrically connected to the data lines 1 on the two sides of the display region AA can be made smaller, the volumes of the first compensation structures 20 connected to the data lines 1 on the two sides of the display region AA can be made smaller, and the space occupied by the first compensation structures 20 connected to the data lines 1 on the two sides of the display region AA in the peripheral region BB is smaller, which facilitates the narrow bezel design of the display panel 100.

Lines of the center lines of the plurality of fourth electrodes 31 connecting the center of the display region AA have included angles in a range from 30° to 50° with the first direction X. That is, an included angle between a line connecting the center of the second compensation structure 30 and the center of the display region AA and the first direction X is in a range from 30° to 50°. It has been verified that within the above included angle range, a ratio of a size of a required compensation capacitor to a spacing between the gate driving circuit 112 and the display region AA is the largest. That is, it is most difficult to set the compensation capacitor in this region. By providing the second compensation structure 30 within the above included angle range, it is beneficial to reducing the spacing between the gate driving circuit 112 and the display region AA, and in turn to reducing the width of the peripheral region BB.

In some embodiments, the second compensation structure 30 includes a plurality of fifth electrodes 32 and a plurality of sixth electrodes 33. Each fifth electrode 32 corresponds to a sixth electrode 33, which means that an orthographic projection of a fifth electrode 32 on the substrate 101 and an orthographic projection of a sixth electrode 33 on the substrate 101 have an overlapping region, and a fifth electrode 32 and a sixth electrode 33 that correspond to each other are located in the same first gap 50; and two adjacent fifth electrodes 32 and two adjacent six electrodes 33 have at least one shift register sub-circuit 1121. For example, two adjacent fifth electrodes 32 and two adjacent six electrodes 33 have therebetween one shift register sub-circuit 1121, two shift register sub-circuits 1121, or three shift register sub-circuits 1121, which is not limited in the embodiments of the present disclosure. Orthographic projections of the fifth electrode 32, the sixth electrode 33 and at least one fourth electrode 31 that are located in the same first gap 50 on the substrate 101 overlap.

Each first gap 50 may have multiple fourth electrodes 31, for example, the number of fourth electrodes 31 may be 3, 4, 5, 6, or 9, which is not limited in this embodiment.

In some embodiments, the at least one fourth electrode 31 and the first electrodes 21 are arranged in the same layer. The first electrodes 21 and the fourth electrode 31 may be formed through one patterning process. In the way, it may be possible to reduce the number of patterning times, save the manufacturing costs and improve the manufacturing efficiency.

The at least one fifth electrode 32 and the second electrode 22 are arranged in the same layer. The second electrode 22 and the fifth electrode 32 may be formed through one patterning process. In the way, it may be possible to reduce the number of patterning times, save the manufacturing costs and improve the manufacturing efficiency.

The at least one sixth electrode 33 and the third electrode 23 are arranged in the same layer. The third electrode 23 and the sixth electrode 33 may be formed through one patterning process. In the way, it may be possible to reduce the number of patterning times, save the manufacturing costs and improve the manufacturing efficiency.

In some embodiments, the display panel 100 further includes a second compensation structure 30, the second compensation structure 30 includes at least one fourth electrode 31 and at least one fifth electrode 32, and orthographic projections of the at least one fourth electrode 31 and the at least one fifth electrode 32 on substrate 101 have an overlapping region. In this way, the at least one fourth electrode 31 and the at least one fifth electrode 32 constitute only one compensation capacitor, i.e., a third compensation capacitor. Each fourth electrode 31 is electrically connected to a first electrode. That is, the first compensation structure 20 and the second compensation structure 30 together perform the RC loading compensation on the data lines 1. The at least one fourth electrode 31 is located in the first gap. That is, the second compensation structure 30 is located in the first gap 50. The second compensation structure 30 may also compensate part of RC loadings required by the data lines 1. In this way, the volume of the first compensation structure 20 located between the display region AA and the initialization signal bus 111 can be made smaller, the space occupied by the first compensation structure 20 in the peripheral region is smaller, and the width of the peripheral region BB of the display panel 100 can be reduced.

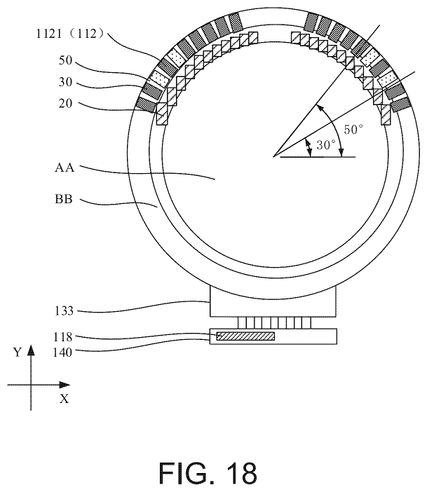

In some embodiments, as shown in FIG. 17, when the display panel 100 includes the second compensation structure 30, the test unit 118 may be arranged in the bonding region 133. Alternatively, as shown in FIG. 18, the display apparatus 1000 further includes a circuit board 140, the circuit board 140 is electrically connected to the bonding region 133, and the test unit 118 is located on the circuit board 140.

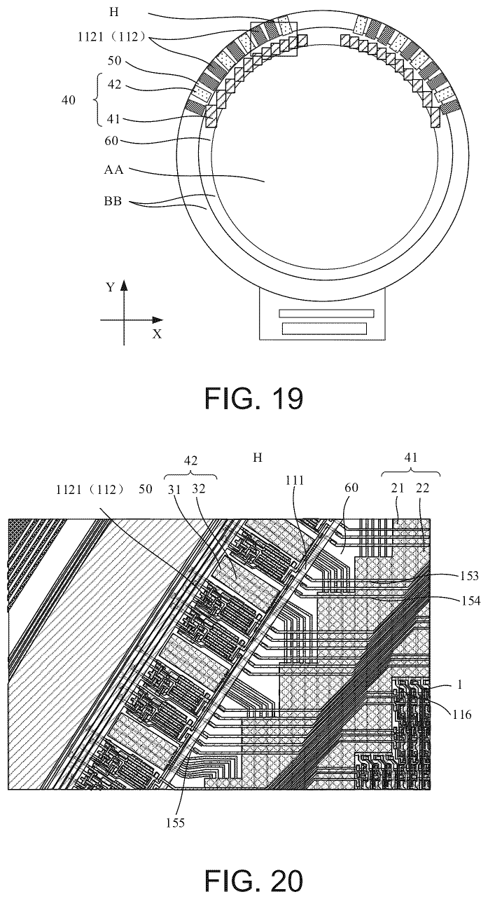

Some embodiments of the present disclosure further provide a display panel 100. As shown in FIG. 19, the display panel 100 includes a gate driving circuit 112, a plurality of data lines 1 (not shown in the figure), and a third compensation structure 40. The gate driving circuit 112 is located on a side of the display region AA. The gate driving circuit 112 includes a plurality of shift register sub-circuits 1121; at least a group of two adjacent shift register sub-circuits 1121 has a first gap 50 therebetween; and the gate driving circuit 112 and the display region AA have a second gap 60 therebetween. The plurality of data lines 1 are located in the display region AA. Lengths of at least two data lines 1 among the plurality of data lines 1 are not equal. In this way, at least two data lines 1 have different RC loadings. The third compensation structure 40 is located in the peripheral region BB, and the third compensation structure 40 is used to compensate for difference in RC loadings of the above-mentioned different data lines 1. As shown in FIG. 20, the third compensation structure 40 includes: a plurality of first electrodes 21 and at least one second electrode 22 that are located in the second gap 60, and at least one fourth electrode 31 and at least one fifth electrode 32 that are located in the first gap 50. An orthographic projection of the at least one second electrode 22 on the substrate 101 overlaps with orthographic projections of the plurality of first electrodes 21 on the substrate 101. In this way, the at least one second electrode 22 and the plurality of first electrodes 21 constitute a fifth compensation capacitor 41. The fifth compensation capacitor 41 can compensate part of RC loadings required by the data lines 1. An orthographic projection of the at least one fifth electrode 32 on the substrate 101 overlaps with an orthographic projection of the at least one fourth electrode 31 on the substrate 101. In this way, the at least one fifth electrode 32 and the at least one fourth electrode 32 constitute a sixth compensation capacitor 42, and the sixth compensation capacitor 42 can also compensate part of RC loading required by the data lines 1. Each first electrode 21 is electrically connected to a data line 1, and the fifth compensation capacitor 41 can perform the RC loading compensation on the data lines 1, so that the RC loadings between the data lines 1 of different lengths are approximately equal, and the risk of poor display of the display panel 100 is reduced. Each fourth electrode 31 is electrically connected to a first electrode 21, and the at least one fifth electrode 32 is electrically connected to the at least one second electrode 22. In this way, the fifth compensation capacitor 41 and the sixth compensation capacitor 42 together perform the RC loading compensation on the data lines 1. Since the sixth compensation capacitor 42 is located in the first gap 50 and the sixth compensation capacitor 42 compensates part of RC loadings required by the data lines 1, the volume of the fifth compensation capacitor 41 located in the second gap 60 can be made small. Therefore, the fifth compensation capacitor 41 occupies a small space in the peripheral region BB. As a result, the width of the peripheral region of the display panel may be reduced.

In some embodiments, the display panel 100 further includes an active layer 102, a first gate dielectric layer 103, and a first gate conductive layer 104, a second gate dielectric layer 105, a second gate conductive layer 106, an interlayer dielectric layer 107, a source-drain conductive layer 108, a planarization layer 109 and an anode layer 110 that are stacked in the direction perpendicular to the substrate 101 and away from the substrate 101 (a direction from bottom to top in FIG. 4A). The materials and structures of the active layer 102, the first gate dielectric layer 103, the first gate conductive layer 104, the second gate dielectric layer 105, the second gate conductive layer 106, the interlayer dielectric layer 107, the source-drain conductive layer 108, the planarization layer 109 and the anode layer 110 in this embodiment may be the same as or different from the materials and structures of the corresponding film layers in the above embodiments, and details will not be repeated here.

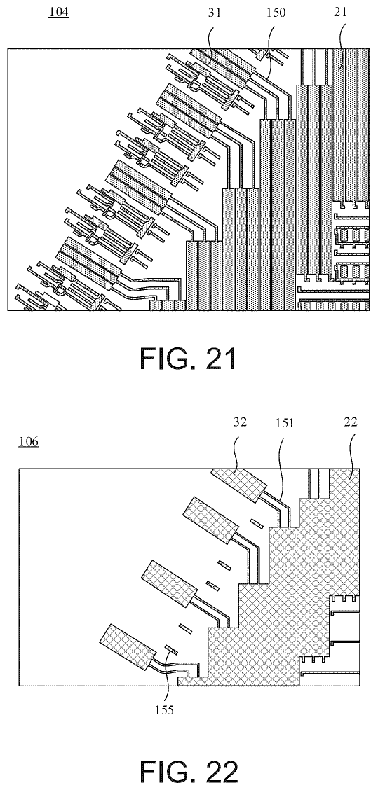

As shown in FIG. 21, the first electrodes 21 and the fourth electrode 31 are located in the first gate conductive layer 104. The first electrodes 21, the fourth electrode 31 and the first gate conductive layer 104 may be formed through one patterning process. In the way, it may be possible to reduce the number of patterning times, save the manufacturing costs and improve the manufacturing efficiency.

As shown in FIG. 22, the second electrode 22 and the fifth electrode 32 are located in the second gate conductive layer 106. The second electrode 22, the fifth electrode 32 and the second gate conductive layer 106 may be formed through one patterning process. In the way, it may be possible to reduce the number of patterning times, save the manufacturing costs and improve the manufacturing efficiency.

The display panel 100 further includes fifth connection line(s) 150 and sixth connection line(s) 151, as shown in FIGS. 21 and 22. The fifth connection line(s) 150 are located in the first gate conductive layer 104. An end of the fifth connection line is electrically connected to a first electrode 21, and another end of the fifth connection line is electrically connected to a fourth electrode 31. The sixth connection line(s) 151 are located in the second gate conductive layer 106. An end of the sixth connection line 151 is electrically connected to a second electrode 22, and another end of the sixth connection line 151 is electrically connected to a fifth electrode 32.

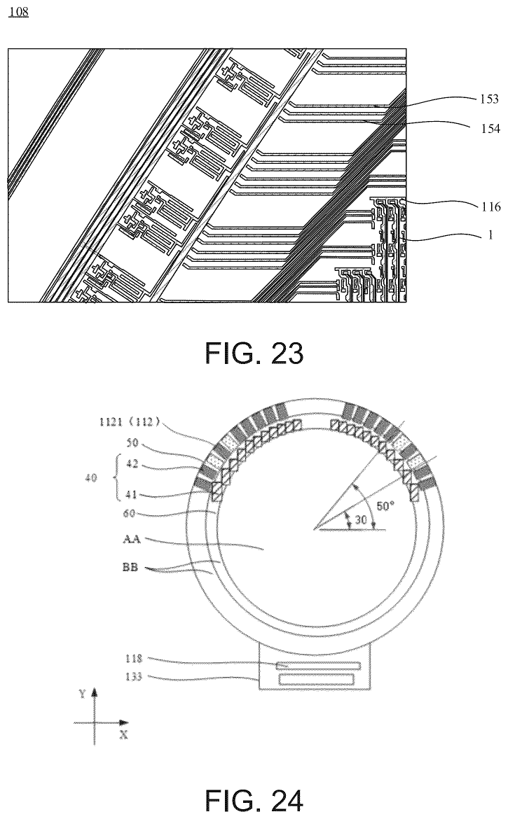

In some embodiments, as shown in FIG. 23, the display panel 100 further includes an initialization signal bus 111, seventh connection line(s) 153 and eighth connection line(s) 154.

The initialization signal bus 111 is located in the peripheral region BB, and at least partially surrounds the display region AA. The initialization signal bus 111 is configured to initialize voltages of two ends of a storage capacitor and a voltage of an anode of a light-emitting element.

As shown in FIG. 23, the seventh connection line(s) 153 are located in the source-drain conductive layer 108. An end of the seventh connection line 153 is electrically connected to the gate driving circuit 112, and another end of the seventh connection line 153 is electrically connected to a row of pixel circuits 10. The eighth connection line(s) 154 are located in the source-drain conductive layer 108. An end of the eighth connection line 154 is electrically connected to the initialization signal bus 111, and another end of the eighth connection line 154 is electrically connected to a row of pixel circuits 10. The seventh connection line(s) 153 and the eighth connection line(s) 154 extend above the third compensation structure 40.

The fifth compensation capacitor 41 is located between the plurality of pixel circuits 10 and the initialization signal bus 111, and the seventh connection line(s) 153 and the eighth connection line(s) 154 extend above the fifth compensation capacitor 41.

The display panel 100 further includes a VDD bus (not shown in the figure) and a plurality of VDD signal lines 116 (as shown in FIG. 23).

The plurality of VDD signal lines 116 are located in the display region AA, and are located in the source-drain conductive layer 108. Each column of pixel circuits 10 is electrically connected to a VDD signal line 116; and the plurality of VDD signal lines 116 are electrically connected to the VDD bus. The at least one second electrode 22 is electrically connected to the plurality of VDD signal lines 116.

The display panel 100 further includes ninth connection line(s) 155, as shown in FIG. 20. An end of the ninth connection line 155 is electrically connected to an eighth connection line 154, and another end thereof is electrically connected to the initialization signal bus 111. The ninth connection line(s) 155 are located in the second gate conductive layer 106, and extend below the initialization signal bus 111.

In some embodiments, the shape of the display region AA is approximately circular. The third compensation structure 40 includes a plurality of fourth electrodes 31, and the number of the fourth electrodes 31 is less than the number of the first electrodes 21. As shown in FIG. 19, when a border of the display region AA is in a shape of a circle, the compensated RC loadings required by the data lines 1 are decreasing from the two sides of the display region AA to the middle of the display region AA. The volumes of the third compensation structures 40 connected to the data lines 1 are decreasing from the two sides of the display region AA to the middle of the display region AA. The third compensation structures 40 connected to the data lines 1 on the two sides of the display region AA have the largest volumes, and the third compensation structures 40 connected to the data lines 1 in the middle of the display region AA have the smallest volumes. The fourth electrodes 31 are electrically connected to the first electrodes 21 that are electrically connected to the data lines 1 on the two sides of the display region AA. The fifth compensation capacitors 41 located on the two sides and the sixth compensation capacitors 42 connected thereto together perform the RC loading compensation on the data lines 1. Since the six compensation capacitors 42 corresponding to the fifth compensation capacitors 41 that are located on the two sides are located in the second gap 60, the six compensation capacitors 42 corresponding to the fifth compensation capacitors 41 located on the two sides in the display region AA can be made small. The six compensation capacitors 42 corresponding to the fifth compensation capacitors 41 located on the two sides occupy a small space in the peripheral region BB. Therefore, the width of the peripheral region BB of the display panel 100 may be reduced.

Lines connecting the plurality of fourth electrodes 31 to the center of the display region AA have included angles in a range from 30° to 50° with the first direction X. That is, an included angle between a line connecting the center of the sixth compensation capacitor 42 and the center of the display region AA and the first direction X is in a range from 30° to 50°. It has been verified that within the above included angle range, a ratio of a size of a required compensation capacitor to a spacing between the gate driving circuit 112 and the display region AA is the largest. That is, it is most difficult to set the compensation capacitor in this region. By providing the sixth compensation capacitor 42 within the above included angle range, it is beneficial to reducing the spacing between the gate driving circuit 112 and the display region AA, and in turn to reducing the width of the peripheral region BB.

In some embodiments, the third compensation structure 40 includes a plurality of fifth electrodes 32, and two adjacent fifth electrodes 32 have at least one shift register sub-circuit 1121 therebetween. For example, two adjacent fifth electrodes 32 have one shift register sub-circuit 1121, two shift register sub-circuits 1121, or three shift register sub-circuits 1121 therebetween, which is not limited in the embodiments of the present disclosure. Orthographic projections of the fifth electrode 32 and at least one fourth electrode 31 located in the same first gap 50 on the substrate 101 overlap.

In some embodiments, the at least one fourth electrode 31 and the plurality of first electrodes 21 are arranged in the same layer. The first electrodes 21 and the fourth electrode 31 may be formed through one patterning process. In the way, it may be possible to reduce the number of patterning times, save the manufacturing costs and improve the manufacturing efficiency.

At least one fifth electrode 32 and at least one second electrode 22 are arranged in the same layer. The second electrode 22 and the fifth electrode 32 may be formed through one patterning process. In the way, it may be possible to reduce the number of patterning times, save the manufacturing costs and improve the manufacturing efficiency.

In some embodiments, as shown in FIG. 24, when the display panel 100 includes the third compensation structure 40, the test unit 118 may be arranged in the bonding region 133. Alternatively, as shown in FIG. 18, the display apparatus 1000 further includes a circuit board 140, the circuit board 140 is electrically connected to the bonding region 133, and the test unit 118 is located on the circuit board 140.

In the description of the specification, specific features, structures, materials or characteristics may be combined in any suitable manner in any one or more embodiments or examples.

The foregoing descriptions are merely specific implementation manners of the present disclosure, but the protection scope of the present disclosure is not limited thereto. Any person skilled in the art could readily conceive of changes or replacements within the technical scope of the present disclosure, which shall all be included in the protection scope of the present disclosure. Therefore, the protection scope of the present disclosure shall be subject to the protection scope of the claims.

1. A display panel, having a display region and a peripheral region surrounding the display region, the display panel comprising:
a substrate;
a plurality of data lines located in the display region; lengths of at least two of the plurality of data lines being not equal; and
a first compensation structure located in the peripheral region and including first electrodes, a second electrode and a third electrode, wherein each of the first electrodes is electrically connected to a data line, and the second electrode is configured to transmit a common voltage signal; and orthographic projections of the first electrodes, the second electrode and the third electrode on the substrate have overlapping regions.

2. The display panel according to claim 1, further comprising: an active layer, a first gate conductive layer, a second gate conductive layer, a source-drain conductive layer, and an anode layer that are stacked in a direction perpendicular to the substrate and away from the substrate, wherein
the first electrodes are located in the first gate conductive layer, the second electrode is located in the second gate conductive layer, and the plurality of data lines are located in the source-drain conductive layer.

3. The display panel according to claim 2, wherein the third electrode is located in the active layer, and a material of the third electrode includes a conductive semiconductor material.

4. The display panel according to claim 3, further comprising:
a plurality of pixel circuits located in the display region, wherein the plurality of pixel circuits are arranged in a plurality of rows and a plurality of columns, and each column of pixel circuits is electrically connected to at least one data line;
an initialization signal bus located in the peripheral region and at least partially surrounding the display region;
a gate driving circuit located on a side of the initialization signal bus away from the display region;
a first connection line located in the source-drain conductive layer, wherein an end of the first connection line is electrically connected to the gate driving circuit, and another end of the first connection line is electrically connected to a row of pixel circuits; and
a second connection line located in the source-drain conductive layer, wherein an end of the second connection line is electrically connected to the initialization signal bus, and another end of the second connection line is electrically connected to a row of pixel circuits;
wherein the first compensation structure is located between the plurality of pixel circuits and the initialization signal bus, and the first connection line and the second connection line extend above the first compensation structure.

5. The display panel according to claim 2, wherein the third electrode is located in the source-drain conductive layer.

6. The display panel according to claim 5, further comprising:
a plurality of pixel circuits located in the display region, wherein the plurality of pixel circuits are arranged in a plurality of rows and a plurality of columns, and each column of pixel circuits is electrically connected to at least one data line;
an initialization signal bus located on a side of the first compensation structure away from the display region and at least partially surrounding the display region;
a gate driving circuit located on a side of the initialization signal bus away from the display region;
a first connection line located in the anode layer, wherein an end of the first connection line is electrically connected to the gate driving circuit, and another end of the first connection line is electrically connected to a row of pixel circuits; and
a second connection line located in the anode layer, wherein an end of the second connection line is electrically connected to the initialization signal bus, and another end of the second connection line is electrically connected to a row of pixel circuits;
wherein the first compensation structure is located between the plurality of pixel circuits and the initialization signal bus, and the first connection line and the second connection line extend above the first compensation structure.

7. The display panel according to claim 6, wherein the common voltage signal is a voltage drain drain (VDD) signal; and the display panel further comprises:
a VDD bus located between the first compensation structure and the initialization signal bus and located in the source-drain conductive layer; and
a plurality of VDD signal lines located in the display region and located in the source-drain conductive layer; each column of pixel circuits being electrically connected to a VDD signal line; the plurality of VDD signal lines being electrically connected to the VDD bus;
wherein the second electrode is electrically connected to the plurality of VDD signal lines.

8. The display panel according to claim 7, further comprising:
a third connection line, an end thereof being electrically connected to the second connection line and another end thereof being electrically connected to the initialization signal bus; and the third connection line being located in the second gate conductive layer and extending below the VDD bus.

9. The display panel according to claim 6, further comprising:
a test unit located between the gate driving circuit and the initialization signal bus;
a fourth connection line, an end thereof being electrically connected to the test unit and another end thereof being electrically connected to a first electrode; the fourth connection line being located in the first gate conductive layer and extending below the VDD bus and the initialization signal bus; and
a fifth connection line, an end thereof being electrically connected to the gate driving circuit and another end thereof being electrically connected to the first connection line; the fifth connection line being located in the first gate conductive layer and extending below the VDD bus and the initialization signal bus.

10. (canceled)

11. The display panel according to claim 1, wherein
the first compensation structure includes a plurality of first electrodes and a plurality of second electrodes, each second electrode corresponds to a first electrode, and orthographic projections of the first electrode and the second electrode that correspond to each other on the substrate overlap; or
the first compensation structure includes a plurality of first electrodes and one second electrode, and orthographic projections of the plurality of first electrodes on the substrate overlap with an orthographic projection of the second electrode on the substrate; or
the first compensation structure includes a plurality of first electrodes and a plurality of third electrodes, each third electrode corresponds to a first electrode, and orthographic projections of the first electrode and the third electrode that correspond to each other on the substrate overlap; or
the first compensation structure includes a plurality of first electrodes and one third electrode, and orthographic projections of the plurality of first electrodes on the substrate overlap with an orthographic projection of the third electrode on the substrate.

12. (canceled)

13. The display panel according to claim 1, wherein the display region is approximately circular; in a first direction and from two sides of the display region to a center line of the display region along a second direction, length of the plurality of data lines increase in a stepwise manner; the second direction is parallel to an extension direction of the data lines, and the first direction is perpendicular to the second direction;
borders of the display region include two opposite first straight line borders, two opposite second straight line borders, and four polyline borders; the first straight line borders extend along the second direction; the second straight line borders extend along the first direction; and each polyline border is located between adjacent first straight line border and second straight line border,
among the four polyline borders, two polyline borders close to a bonding region are first polyline borders, and two polyline borders far away from the bonding region are second polyline borders; sides of the two first polyline borders away from a center of the display region are each provided with one first compensation structure, and/or sides of the two second polyline borders away from the center of the display region are each provided with one first compensation structure.

14. The display panel according to claim 13, wherein sides of the four polyline borders away from the center of the display region are each provided with one first compensation structure.

15. The display panel according to claim 1, further comprising:
a gate driving circuit located on a side of the first compensation structure away from the display region and including a plurality of shift register sub-circuits, at least a group of two adjacent shift register sub-circuits having a first gap therebetween;
a second compensation structure including at least one fourth electrode, at least one fifth electrode and at least one sixth electrode, wherein the at least one fourth electrode is located in the first gap, each fourth electrode is electrically connected to a first electrode, and orthographic projections of the at least one fourth electrode, the at least one fifth electrode and the at least one sixth electrode on the substrate have an overlapping region.

16. The display panel according to claim 15, wherein the second compensation structure includes a plurality of fourth electrodes, and a number of the fourth electrodes is equal to a number of the first electrodes; or
a border of the display region is approximately circular; the second compensation structure includes a plurality of fourth electrodes; a number of the fourth electrodes is less than a number of the first electrodes; and lines connection centers of the plurality of fourth electrodes to a center of the display region have included angles in a range from 30° to 50° with a first direction; wherein the first direction is perpendicular to an extension direction of the data lines.

17. (canceled)

18. The display panel according to claim 16, wherein the second compensation structure includes a plurality of fifth electrodes and a plurality of sixth electrodes; each fifth electrode corresponds to a sixth electrode, and the fifth electrode and the sixth electrode that correspond to each other are located in the same first gap; two adjacent fifth electrodes and two adjacent sixth electrodes have at least one shift register sub-circuit therebetween; and
orthographic projections of the fifth electrode, the sixth electrode and at least one fourth electrode located in the same first gap on the substrate overlap.

19. (canceled)

20. A display panel, having a display region and a peripheral region surrounding the display region, the display panel comprising:
a substrate;
a gate driving circuit located on a side of the display region and including a plurality of shift register sub-circuits, at least a group of two adjacent shift register sub-circuits having a first gap therebetween, and the gate driving circuit and the display region having a second gap therebetween;
a plurality of data lines located in the display region, lengths of at least two of the plurality of data lines being not equal; and
a third compensation structure located in the peripheral region and including: a plurality of first electrodes and at least one second electrode that are located in the second gap, and at least one fourth electrode and at least one fifth electrode that are located in the first gap; wherein each of the plurality of first electrodes is electrically connected to a data line; an orthographic projection of the at least one second electrode on the substrate overlaps with orthographic projections of the plurality of first electrodes on the substrate; each fourth electrode is electrically connected to a first electrode; the at least one fifth electrode is electrically connected to the at least one second electrode; and an orthographic projection of the at least one fifth electrode on the substrate overlaps with an orthographic projection of the at least one fourth electrode on the substrate.

21. The display panel according to claim 20, further comprising:
an active layer, a first gate conductive layer, a second gate conductive layer, a source-drain conductive layer, and an anode layer that are stacked in a direction perpendicular to the substrate and away from the substrate, wherein the plurality of first electrodes and the at least one fourth electrode are located in the first gate conductive layer, and the at least one second electrode and the at least one fifth electrode are located in the second gate conductive layer;
or
an active layer, a first gate conductive layer, a second gate conductive layer, a source-drain conductive layer, and an anode layer that are stacked in a direction perpendicular to the substrate and away from the substrate, a fifth connection line located in the first gate conductive layer, and a sixth connection line located in the first gate conductive layer, wherein the plurality of first electrodes and the at least one fourth electrode are located in the first gate conductive layer; and the at least one second electrode and the at least one fifth electrode are located in the second gate conductive layer; an end of the fifth connection line is electrically connected to the first electrode, and another end of the fifth connection line is electrically connected to a fourth electrode; and an end of the sixth connection line is electrically connected to a second electrode, and another end of the sixth connection line is electrically connected to a fifth electrode.

22. (canceled)

23. The display panel according to claim 20, wherein the third compensation structure includes a plurality of fourth electrodes, and a number of the fourth electrodes is equal to a number of the first electrodes; or
a shape of the display region is approximately circular; the third compensation structure includes a plurality of fourth electrodes; a number of the fourth electrodes is less than a number of the first electrodes; lines connecting the plurality of fourth electrodes to a center of the display region have included angles in a range from 30° to 50° with a first direction being perpendicular to an extension direction of the data lines.

24. (canceled)

25. The display panel according to claim 23, wherein the third compensation structure includes a plurality of fifth electrodes; two adjacent fifth electrodes have at least one shift register sub-circuit therebetween; and orthographic projections of a fifth electrode and at least one fourth electrode located in the same first gap on the substrate overlap.

26. A display apparatus, comprising the display panel according to claim 1.
